(19) United States
(12) Patent Application Publication
(10) Pub. No.: US 2019/0363010 A1
(43) Pub. Date: Nov. 28, 2019

(54) METHODS OF INCREASING ADHESION BETWEEN A CONDUCTIVE METAL AND AN OXIDE SUBSTRATE AND ARTICLES MADE THEREFROM

(71) Applicant: CORNING INCORPORATED, Corning, NY (US)

(72) Inventors: Philip Simon Brown, Big Flats, NY (US); Yunfeng Gu, Painted Post, NY (US); Mandakini Kanungo, Painted Post, NY (US); Prantik Mazumder, Ithaca, NY (US); Rajesh Vaddi, Coming, NY (US)

(21) Appl. No.: 16/413,777

(22) Filed: May 16, 2019

Related U.S. Application Data
(60) Provisional application No. 62/675,276, filed on May 23, 2018.

(51) Int. Cl. H01L 21/768; C23C 18/16; C23C 18/38

(52) U.S. Cl. CPC H01L 21/76877; C23C 18/1639; C03C 17/007; H01L 2225/107; C23C 18/38

(57) ABSTRACT

A method for bonding a conductive metal to an oxide substrate includes applying a porous coating to a surface of the oxide substrate, the porous coating including a porous oxide and catalyst nanoparticles dispersed therein, and depositing a conductive metal onto the porous coating. A portion of the conductive metal may be deposited within the pores of the porous coating to couple the conductive metal to the porous coating. Articles are also disclosed that include the oxide substrate, the porous coating coupled to a surface of the oxide substrate, and the conductive metal coupled to the porous coating. The porous coating may include a porous oxide and catalyst nanoparticles dispersed within the metal oxide. A portion of the conductive metal may be deposited within the pores of the porous coating to interlock the conductive metal to the porous coating.

This application claims the benefit of priority to U.S. Provisional Application Ser. No. 62/675,276 filed on May 23, 2018, the content of which is relied upon and incorporated herein by reference in its entirety.

### BACKGROUND

### Field

The present specification generally relates to oxide substrates coated with electrically conductive metals, in particular to methods for coupling electrically conductive metals to surfaces of oxide substrates and articles produced therefrom.

### Technical Background

3D interposers with through package via interconnects (TPV interconnects) that connect a logic device on one side and a memory on the other side are becoming popular for high bandwidth devices. Substrates, such as silicon, have been used as an interposer disposed between electrical components (e.g., printed circuit boards, integrated circuits, and the like). Metalized through-substrate vias provide a path through the interposer for electrical signals to pass between opposite sides of the interposer. Many conventional 3D interposers include an organic or silicon substrate. However, organic interposers suffer from poor dimensional stability, and silicon wafers are expensive and exhibit high dielectric loss due to semiconducting properties of the silicon.

Oxide substrates, such as glass or ceramic substrates, are attractive materials that are highly advantageous for electrical signal transmission, as they have excellent thermal dimensional stability due to a low coefficient of thermal expansion (CTE), as well as very good low electrical loss at high frequencies, and the possibility of being formed at thickness as well as at large panel sizes. However, metallization of through-vias and other features of glass substrates and other oxide substrates presents significant challenges.

### SUMMARY

Accordingly, a need exists for methods of coupling/bonding an electrically conductive metal to a surface of an oxide substrate. Additionally, a need exists for articles having an electrically-conductive metal securely coupled to the surface of the oxide substrate.

According to one or more aspects of the present disclosure, a method for coupling a conductive metal to an oxide substrate may include applying a porous coating to a surface of the oxide substrate, the porous coating including a porous oxide and a plurality of catalyst nanoparticles dispersed within the porous oxide. The method may further include depositing a conductive metal onto the porous coating. At least a portion of the conductive metal may be deposited within the pores of the porous coating to couple the conductive metal to the porous coating.

According to one or more other aspects of the present disclosure, an article may include an oxide substrate and a porous coating coupled to a surface of the oxide substrate, the porous coating including a porous oxide and a plurality of catalyst nanoparticles dispersed within the porous oxide. The article may further include a conductive metal coupled to the porous coating, where at least a portion of the conductive metal may penetrate into a plurality of pores of the porous coating to interlock the conductive metal to the porous coating.

According to one or more other aspects of the present disclosure, an electrical device may include at least one electrical component coupled to a first side or a second side of an article, the article including an oxide substrate having at least one via, a porous coating coupled to a surface of the oxide substrate that define the at least one via, and a conductive metal coupled to the porous coating. The porous coating may include a porous oxide and a plurality of catalyst nanoparticles dispersed within the porous oxide. At least a portion of the conductive metal may penetrate into a plurality of pores of the porous coating to interlock the conductive metal to the porous coating.

According to one or more other aspects of the present disclosure, a method for coupling a conductive metal to an oxide substrate may include applying a coating mixture to a surface of the oxide substrate, the coating mixture comprising an oxide solid particulate and a plurality of catalyst nanoparticles; heat treating the coating mixture to form a porous coating on the surface of the oxide substrate, the porous coating comprising a porous oxide having pores and a plurality of catalyst nanoparticles dispersed within the porous oxide; and depositing the conductive metal onto the porous coating, wherein at least a portion of the conductive metal is deposited within the pores of the porous coating to couple the conductive metal to the porous coating.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a perspective view of a 3D interposer, according to one or more embodiments described herein;

FIG. 2 schematically depicts a cross-sectional view of the 3D interposer of FIG. 1, according to one or more embodiments described herein;

FIG. 3 graphically depicts the enthalpy of formation of metal oxides for various metals;

FIGS. 4A-4E schematically depict a prior art method of bonding a conductive metal to a surface of a substrate;

FIG. 5 schematically depicts an article having a porous coating bonded to a surface of a substrate and a conductive metal coupled to the porous coating, according to one or more embodiments described herein;

FIG. 6 schematically depicts another article having a through via, a porous coating bonded to a surface of a substrate defining the through via, and a conductive metal coupled to the porous coating, according to one or more embodiments described herein;

FIG. 7 schematically depicts another article of the present disclosure having a plurality of channels, a porous coating bonded to a surface of a substrate defining the channels, and a conductive metal coupled to the porous coating, according to one or more embodiments described herein; and

FIG. 8 schematically depicts an electrical device including the article of FIG. 6, according to one or more embodiments described herein.

### DETAILED DESCRIPTION

The present disclosure is directed to methods for coupling an electrically conductive metal to a surface of an oxide substrate and articles produced therefrom. Reference will now be made in detail to embodiments of the methods for coupling the electrically conductive metal to the surface of an oxide substrate and articles produced therefrom, examples of which are illustrated in the accompanying drawings. Whenever possible, the same reference numerals will be used throughout the drawings to refer to the same or like parts.

As used in this disclosure, the term “conductive” refers to electrically conductive, unless specifically stated otherwise.

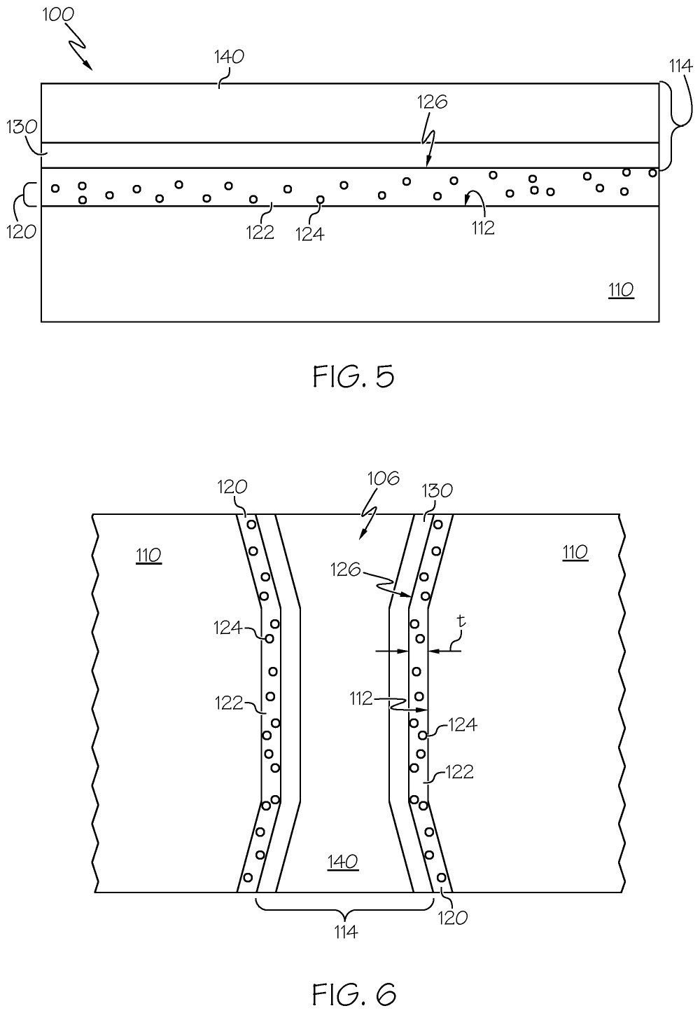

In some embodiments, the methods disclosed herein for coupling a conductive metal to an oxide substrate (glass, ceramic or metal oxide substrate) includes applying a porous coating to a surface of an oxide substrate, the porous coating including a porous oxide and a plurality of catalyst nanoparticles dispersed within the porous oxide. The method further includes depositing a conductive metal onto the porous coating. At least a portion of the conductive metal may be deposited within the pores of the porous coating to couple or interlock the conductive metal to the porous coating. One embodiment of an article 100 produced from the methods described herein is schematically depicted in FIG. 5. Referring to FIG. 5, the article 100 includes the oxide substrate 110, the porous coating 120 coupled to a surface 112 of the oxide substrate 110, and the conductive metal 114 coupled to the porous coating 120. The porous coating 120 may include the porous oxide 122 and the plurality of catalyst nanoparticles 124.

The methods described herein may be used to produce an article, such as an interposer or other electrical component, having one or a plurality of vias passing through a substrate from one surface of the substrate to another surface of the substrate. As used herein, the term “interposer” generally refers to any structure that extends or completes an electrical connection through the structure, for example, but not limited to, between two or more electronic devices disposed on opposite surfaces of the interposer. The two or more electronic devices may be co-located in a single structure or may be located adjacent to one another in different structures such that the interposer functions as a portion of an interconnect nodule or the like. As such, the interposer may contain one or more active areas in which vias and other interconnect conductors (such as, for example, power, ground, and signal conductors) are present and formed. The interposer may also include one or more active areas in which blind vias are present and formed. When the interposer is formed with other components, such as dies, underfill materials, encapsulants, and/or the like, the interposer may be referred to as an interposer assembly. Also, the term “interposer” may further include a plurality of interposers, such as an array of interposers or the like.

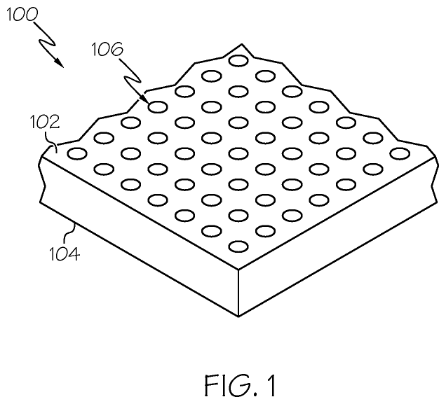

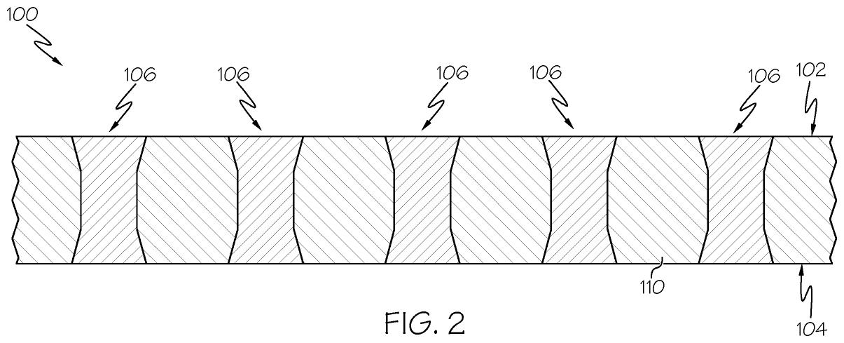

Referring to FIG. 1, an example article 100 comprising an oxide substrate 110 is schematically depicted in a partial perspective view. The oxide substrate 110 includes a first surface 102 and a second surface 104 opposite from the first surface 102. A plurality of vias 106 extends through the bulk of the oxide substrate 110 from the first surface 102 to the second surface 104. It should be understood that any number of vias 106 may extend through the oxide substrate 110 in any arrangement. FIG. 2 provides a cross-sectional view of the article 100 that includes the oxide substrate 110 and a plurality of vias 106 extending through the oxide substrate 110 from the first surface 102 to the second surface 104.

The vias 106 may be filled by plating process wherein the conductive metal 114 (e.g., copper) is deposited on the sidewalls of the via 106 and progressively built-up until the via 106 is hermetically sealed. The vias 106 may have an hourglass shape having a narrow waist that provides a metal “bridge” for the electrically conductive metal 114 to be initially deposited. The electrically conductive metal 114 is deposited on both sides of this bridge until the via 106 is filled with the electrically conductive metal 114. Although described in relation to interposers having electrically conductive vias, the methods and compositions disclosed herein may also be used to couple conductive metals to the surface of metal oxide substrates having other features, such as flat surfaces or channels.

Properties of silica, alumina, and other metal oxides make these metal oxides desirable substrates for use as interposers in electronic devices. For example, the low coefficient of thermal expansion (CTE) of silica minimizes expansion and movement of the silica-containing substrate due to the application of heat flux, such as heat flux generated by a semiconductor device that is coupled to the silica-containing substrate acting as an interposer. Expansion of the interposer due to CTE mismatch between the interposer and a semiconductor device (or other electronic component) may cause the bond between the interposer and the semiconductor to fail and result in separation or other damage. Additionally, silica-containing substrates provide desirable RF properties over other substrates such as silicon. Desirable RF properties may be important in high frequency applications, such as high-speed data communications applications.

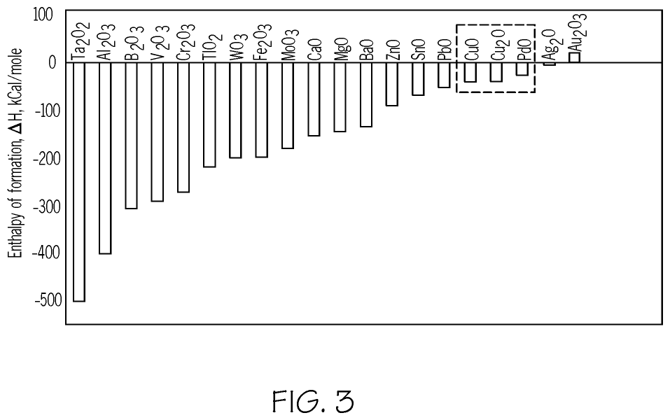

However, the chemical inertness and low intrinsic roughness of oxide substrates, such as glass substrates for example, create challenges when bonding conductive metals to the oxide substrates. For example, some electrically conductive metals, such as copper, nickel, cobalt, or alloys thereof, for example, do not intrinsically bond well to insulators, such as glass, ceramic, and metal oxide substrates, due to the fundamental difference in bonding nature between the electrically conductive metals and glass, ceramic, or metal oxide substrate. Glass, ceramic, and metal oxide substrates are covalently bonded materials that lack free electrons, which makes glass and other oxide substrates electrical insulators. In contrast, the bonding in electrically conductive metals, such as copper, is metallic in nature, which can be conceptualized as a plurality of stationary cationic nuclei and a delocalized sea of electrons acting as a bonding agent (i.e., “glue”) to bond the stationary cationic nuclei together. Therefore, no common bonding mechanism is present at the interface between the conductive metal and a glass, ceramic, or metal oxide substrate. However, if the conductive metal could easily form an oxide at the interface with a glass, ceramic, or metal oxide substrate, the greater bond energy of the resultant oxide of the conductive metal could enable strong adhesion between the two disparate materials (i.e., the conductive metal and a glass or metal oxide substrate). The generally accepted criterion for good adhesion between a conductive metal, such as a metal film, and an oxide substrate, such as a glass, ceramic or metal oxide substrate, is that the conductive metal must be oxygen negative to react chemically with the surface of the oxide substrate, forming an interfacial reaction zone. As used herein, the term “oxygen negative” refers to the degree to which the formation of the oxide of the conductive metal is thermodynamically favorable. For example, a high “oxygen negativity” of a metal indicates that the metal has a large magnitude negative enthalpy of formation of the metal oxide. In other words, oxidation of the metal to the metal oxide is thermodynamically favorable. Conversely, low “oxygen negativity” means that formation of the metal oxide from the metal is not thermodynamically favored. FIG. 3 graphically depicts the enthalpy of formation of oxides of various metals. As shown in FIG. 3, copper, which is a commonly utilized conductive metal, exhibits a small negative enthalpy of formation of the metal oxide (i.e., low oxygen negativity), which is a reason why copper does not form strong bonds with the surfaces of oxide substrates, such as glass, ceramic, or metal oxide substrates.

To overcome this weak bonding, in some conventional plating processes, metallic palladium nanoparticles are used as catalysts to facilitate deposition of the conductive metal onto an oxide substrate, such as depositing copper onto a glass substrate, for example. However, the oxygen negativity of palladium is also very low (i.e., negative enthalpy of formation of palladium oxide is small in magnitude) suggesting that the overall adhesion between glass and copper would be poor even though the copper is uniformly deposited on the glass surface. One conventional technique to overcome these bonding issues, therefore, is to first sputter-deposit an initial metal film with large oxygen negativity (i.e., large magnitude of the enthalpy of formation of the metal oxide) on the oxide surface. Common metals used for this purpose include tantalum, titanium, or chromium. These metals form strong and thin oxide interfacial bonding layers with the glass while remaining metallic in the bulk. As copper is deposited on the top surface of these metals, e.g. by sputtering or by electroplating, the copper forms strong metallic bonds with the adhesion-promoting thin metallic film. The covalent oxide bond between the adhesion-promoting initial metal film and the glass in combination with the metallic bond between the copper and the adhesion-promoting initial metal film may lead to strong effective adhesion between copper and glass. However, conventional sputtering techniques are limited in metalizing the surfaces of the vias in an interposer. Due to the geometry of conventional sputtering techniques, these conventional sputtering techniques are not able to apply the adhesion-promoting initial metal film to high aspect ratio features, such as the surface of a via through the entire thickness of an oxide substrate. Further, sputtering processes are costly in terms of processing equipment and materials.

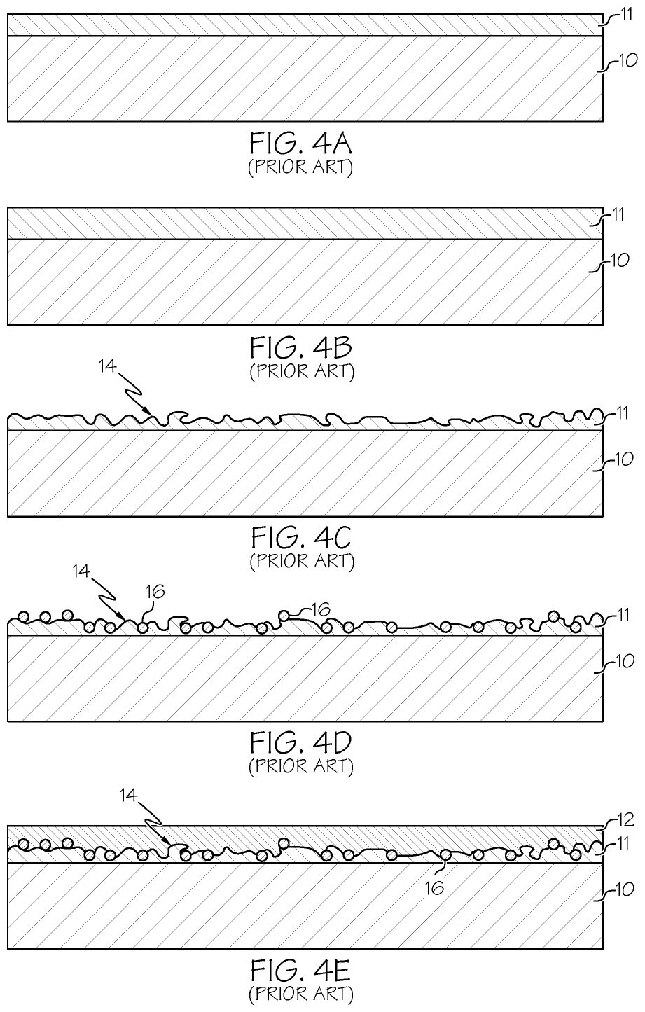

Wet chemistry (solution chemistry) methods for coating the surfaces of an oxide substrate with the conductive metal enables the entire surface of the vias to be coated with the conductive metal and may provide substantial cost savings compared to sputtering methods, among other benefits. In some other conventional wet chemistry methods, the oxide substrate may be coated with a polymer coating before depositing the conductive metal. However, similar adhesion problems occur when bonding the conductive metal to a polymer coating. Referring to FIGS. 4A-4E, in one conventional method of coating a glass substrate 10 with copper 12, the glass substrate 10 is first coated with the polymer coating 11, as shown in FIG. 4A. The bond between the copper 12 and the polymer coating 11 is improved through mechanical interlocking of the copper 12 with the polymer coating 11. Referring to FIGS. 4B and 4C, the interlocking may be achieved by using swelling and etching chemistry to produce a high roughness on the outer surface 14 of the polymer coating 11 with re-entrant geometry in the polymer coating 11. FIG. 4B illustrates swelling of the polymer coating 11 using a swelling agent, and FIG. 4C illustrates the polymer coating 11 following etching to roughen the outer surface 14 of the polymer coating 11. Roughness as high as 1 μm on the outer surface 14 of the polymer coating 11 is often achieved. Referring to FIG. 4D, roughening the outer surface 14 is followed by depositing palladium nanoparticle catalysts 16 into the roughened outer surface 14 of the polymer coating 11. Referring to FIG. 4E, the copper 12 is then electrolessly plated onto the outer surface 14 of the polymer coating 11, which results in mechanical interlocking of the copper 12 with the polymer coating 11, provided that high quality wetting is achieved. This is followed by electroplating thicker copper onto the copper 12 electrolessly plated onto the surface 14. While this approach works well for polymers, it is not always easy to create roughness with re-entrant geometries in glass and other metal oxide substrates.

One of the issues with the previously described mechanical interlocking technique is that the palladium catalysts typically used for electroless plating cannot effectively penetrate the porous network formed during the subtractive or additive approaches previously described herein. Commercially available palladium catalysts for electroless plating typically have average particle sizes in the range of from 10 nanometers (nm) to 80 nm. Thus, in these conventional methods, the palladium catalysts remain at the surface of a porous oxide or polymer coating. If the palladium catalyst remains near the surface, then the copper film that is grown electrolessly will not form a robust mechanical interlock as intended. The only interlocking effect comes from the surface pores of a porous oxide coating or the roughened outer surface of the polymer.

The present disclosure is directed to solution-chemistry-based methods of incorporating the catalytic centers into a porous coating bonded to the surface of an oxide substrate to improve interlocking of the conductive metal with the porous coating. In the methods of the present disclosure, a coating composition and a plurality of catalyst nanoparticles are simultaneously coated onto the surface of a glass, ceramic, or metal oxide substrate, which results in a porous coating having the plurality of catalyst nanoparticles distributed throughout the porous structure of the porous coating. The catalyst nanoparticles distributed throughout the porous coating provide catalytic centers within the porous coating, which enables seeding and deposition of the conductive metal within the porous structure of the porous coating. Referring to FIG. 5, a method for bonding the conductive metal 114 to the oxide substrate 110 of the present disclosure includes applying a porous coating 120 to a surface 112 of the oxide substrate 110, the porous coating 120 comprising a porous oxide 122 and a plurality of catalyst nanoparticles 124 dispersed within the porous oxide 122; and depositing a conductive metal 114 onto the porous coating 120. Penetration of the conductive metal 114 at least partially into the porous coating 120 (i.e., into the pores of the porous coating 120) may couple the conductive metal 114 to the porous coating 120, thereby coupling the conductive metal 114 to the oxide substrate 110.

Referring to FIGS. 5 and 6, the previously described method produces a composite article 100 that includes the porous coating 120 bonded to the surface 112 of the oxide substrate 110 and the conductive metal 114 coupled to the porous coating 120. At least a portion of the conductive metal 114 may be deposited within the pores of the porous coating 120. Catalyzed seeding and deposition of the conductive metal 114 at the catalyst nanoparticles 124 (i.e., catalytic centers) distributed within the porous oxide 122 of the porous coating 120 may cause the conductive metal 114 to be deposited within the pores of the porous coating 120, thereby mechanically interlocking or otherwise coupling the conductive metal 114 to the porous coating 120 and coupling the conductive metal 114 to the surface 112 of the oxide substrate 110.

Mechanically interlocking or otherwise coupling the conductive metal 114 with the porous coating 120 by catalyzing deposition of the conductive metal 114 within the pores of the porous coating 120 may increase the adhesion of the conductive metal 114 to the porous coating 120, thereby increasing adhesion of the conductive metal 114 to the oxide substrate 110 compared to other conventional methods of metallizing oxide substrates with conductive metals. Thus, the methods disclosed herein may result in greater adhesion between the conductive metal 114 and the oxide substrate 110 compared to other conventional metallizing processes. Additionally, by combining the catalyst nanoparticles 124 and the porous oxide 122 into the porous coating 120, the number of processing steps required to electroless deposit the conductive metal 114 onto the oxide substrate 110 may be reduced compared to the prior art method described in conjunction with FIGS. 4A-4E.

The oxide substrate 110 may be a glass, ceramic, glass-ceramic or metal oxide substrate that may include at least one metal oxide, such as silica, alumina, zirconia, titania, other metal oxides, and combinations of these. In some embodiments, the oxide substrate 110 may be a glass or glass ceramic substrate, such as but limited to a silicate glass, an aluminosilicate glass, alkali aluminosilicate glass, alkaline aluminosilicate glass, borosilicate glass, boro-aluminosilicate glass, alkali aluminoborosilicate glass, alkaline aluminoborosilicate glass, soda-lime glass, fused quartz (fused silica), or other type of glass. Example glass substrates may include, but are not limited to, HPFS® fused silica sold by Corning Incorporated of Corning, New York under glass codes 7980, 7979, and 8655, and EAGLE XG® boro-aluminosilicate glass also sold by Corning Incorporated of Corning, New York. Other substrates may include, but are not limited to, Lotus™ NXT glass, Iris™ glass, WILLOW® glass, GORILLA® glass, VALOR® glass, or PYREX® glass sold by Corning Incorporated of Corning, N.Y. The metal oxide substrate 110 may include other commercially-available glass, ceramic, glass-ceramic or metal oxide substrate. In some embodiments, the oxide substrate 110 may be an aluminosilicate glass or a boro-aluminosilicate glass. In other embodiments, the oxide substrate 110 may be a ceramic or glass ceramic substrate that includes at least one of silica, alumina, zirconia, titania, other metal oxide, or combinations of these. In some embodiments, the oxide substrate 110 may include a glass ceramic substrate selected from the group consisting of boron-phosphorous-silica glass ceramic, lithium-alumina-silca glass ceramic, magnesium-alumina-silica glass ceramic, zinc-alumina-silica glass ceramic, and the like.

As previously described, the porous coating 120 may include the porous oxide 122 and the plurality of catalyst nanoparticles 124 dispersed throughout the porous oxide 122. The porous oxide 122 may provide a porous support structure that is securely bonded to the surface 112 of the oxide substrate 110, such as through covalent bonding between the porous oxide 122 and the surface 112 of the oxide substrate 110. In some embodiments, the porous support structure of the porous oxide 122 may have a porosity greater than the porosity of the oxide substrate 110 to which the porous coating 120 is applied. The porous oxide 122 of the porous coating 120 may include silica, alumina, titania, zirconia, ceria, other metal oxide, or combinations of these. In some embodiments, the porous oxide 122 may be selected from the group consisting of silica, alumina, titania, and combinations of these. In some embodiments, the porous oxide 122 may include alumina, such as alpha-alumina, beta-alumina, gamma-alumina, fumed alumina, or other type of alumina. In some embodiments, the porous oxide 122 may be colloidal alumina. In some embodiments, the porous oxide 122 may be silica, such as fumed silica, colloidal silica, or other types of silica. In some embodiments, the porous oxide 122 may be a combination of silica and alumina. In some embodiments, the porous oxide 122 may include alpha-alumina, beta-alumina, gamma-alumina, silica, titania, zirconia, or combinations of these.

The catalyst nanoparticles 124 may include nanoparticles comprised of a metal catalyst. The catalyst nanoparticles 124 may catalyze the deposition of the conductive metal 114 onto the porous coating 120 during electroless plating. Not intending to be bound by theory, it is believed that the metal catalyst of the catalyst nanoparticles 124 may seed deposition of the conductive metal 114 onto the porous coating 120 by providing metallic bonding sites within the porous coating 120 structure. The catalyst nanoparticles 124 may have any shape. For example, in some embodiments, the catalyst nanoparticles 124 may be nanospheres, nanoflakes, nanowires, nanotubes, nanosheets, or combinations of these. In some embodiments, the catalyst nanoparticles 124 may have an irregular shape.

As used herein, the term “nanoparticles” refers to solid particles having an average particle size of from 1 nm to 100 nm as determined by electron microscopy. The catalyst nanoparticles 124 may have an average particle size of from 1 nm to 100 nm. In some embodiments, the catalyst nanoparticles 124 may have an average particle size that is greater than or equal to 50% of the average pore size of the porous coating 120. For example, in some embodiments, the catalyst nanoparticles 124 may have an average particle size of greater than or equal to 60%, greater than or equal to 70%, greater than or equal to 80%, greater than or equal to 90%, or even greater than or equal to 100% of the average pore size of the porous coating 120. In some embodiments, the catalyst nanoparticles 124 may have an average particle size that is from 50% to 200% of the average pore size of the porous coating 120, such as from 50% to 175%, from 50% to 150% from 50% to 100%, from 60% to 200%, from 60% to 175% from 60% to 150%, from 60% to 100%, from 70% to 200%, from 70% to 175% from 70% to 150%, from 70% to 100%, from 80% to 200%, from 80% to 175% from 80% to 150%, from 80% to 100%, from 90% to 200%, from 90% to 175% from 90% to 150%, from 90% to 100%, or from 100% to 200% of the average pore size of the porous coating 120. In some embodiments, the catalyst nanoparticles 124 may have an average particle size that is greater than the average pore size of the porous coating 120. Pore size, porosity, and pore volume are as determined by gas adsorption.

In some embodiments, the metal catalyst of the catalyst nanoparticles 124 may include one or more conductive metals. For example, in some embodiments, the metal catalyst of the catalyst nanoparticles 124 may include silver, gold, cobalt, palladium, platinum, copper, nickel, other conductive metal, or combinations of these. In some embodiments, the catalyst nanoparticles 124 may include a conductive metal catalyst selected from the group consisting of silver, gold, cobalt, palladium, platinum, copper, nickel, or combinations of these.

In some embodiments, the metal catalyst of the catalyst nanoparticles 124 may include one or more conductive metals that do not readily oxidize during processing. In some applications, conductive metals that are prone to oxidation, such as copper and nickel, may form a layer of the oxide of the conductive metal on the outer surface of the nanoparticles, which may reduce the catalytic activity of the catalyst nanoparticles. “Prone to oxidation” means that the metal readily forms an oxide layer on the outer surface in the presence of a source of oxygen, such as air, water, or other oxygen-containing material. In some embodiments, the oxide layer may first be reduced back to the elemental metal state by an additional thermal treatment or other reducing process to activate the catalyst nanoparticles prior to electroless plating. In other embodiments in which the catalyst nanoparticles 124 include metal catalysts that are not prone to oxidation, the methods of bonding the conductive metal 114 to a surface of an oxide substrate 110 may not require reduction of the catalyst nanoparticles 124 to activate the catalytic activity of the catalyst nanoparticles 124, and therefore may require fewer steps in the production process. In some embodiments, the metal catalyst of the catalyst nanoparticles 124 may include silver, gold, cobalt, palladium, platinum, other conductive metal resistant to oxidation, or combinations of these. In some embodiments, the catalyst nanop articles 124 may include a metal catalyst selected from the group consisting of silver, gold, cobalt, palladium, platinum, and combinations of these. In some embodiments, the catalyst nanoparticles 124 may be silver nanoparticles.

In some embodiments, the catalyst nanoparticles 124 may be physically dispersed through the porous coating 120 such that the catalyst nanoparticles 124 are embedded within the porous oxide 122 of the porous coating 120. For example, silver nanoparticles are inert in nature and therefore are not expected to form chemical bonds with the porous oxide 122. Thus, in some embodiments, the catalyst nanoparticles 124 may be primarily mechanically secured within the porous coating 120. In some instances, however, the catalyst nanoparticles 124 may include a conductive metal having a greater magnitude enthalpy of formation of metal oxides such that the metal may form at least some chemical bonds with the porous oxide 122 of the porous coating 120. However, despite the chemical bonding between the catalyst nanoparticles 124 and the porous oxide 122, the catalyst nanoparticles 124 may still be mechanically secured within the porous coating 120.

The porous coating 120 may have a weight ratio of the porous oxide 122 to the catalyst nanoparticles 124 that provides a sufficient number of nucleation sites within the porous coating 120 to seed deposition of the conductive metal 114 during electroless plating. In some embodiments, the porous coating 120 may have a weight ratio of porous oxide 122 to catalyst nanoparticles 124 that enables the catalyst nanoparticles 124 to catalyze bonding of the conductive metal 114 to the porous coating 120 at a number of nucleation sites sufficient to interlock the conductive metal 114 with the porous coating 120. In some embodiments, the porous coating 120 may include a weight ratio of the porous oxide 122 to the catalyst nanoparticles 124 of from 5:1 to 1000:1. For example, in some embodiments, the porous coating may include a weight ratio of the porous oxide 122 to the catalyst nanoparticles 124 of from 5:1 to 500:1, from 5:1 to 100:1, from 5:1 to 75:1, from 5:1 to 50:1, from 10:1 to 1000:1, from 10:1 to 500:1, from 10:1 to 100:1, from 10:1 to 75:1, from 10:1 to 50:1, from 20:1 to 1000:1, from 20:1 to 500:1, from 20:1 to 100:1, from 20:1 to 75:1, or from 20:1 to 50:1. If the weight ratio of the porous metal oxide 122 to the catalyst nanoparticles 124 in the porous coating 120 is less than 5:1, then the density of catalyst nanoparticles 124 in the porous coating 120 may be insufficient to catalyze bonding of the conductive metal 114 to the porous coating 120 during electroless plating, resulting in reduced adhesion of the conductive metal 114 to the porous coating 120 and delamination or cracking of the conductive metal 114 from the surface of the metal oxide substrate 110. In some embodiments, the porous coating 120 may have from 0.1 wt. % to 17.0 wt. % catalyst nanoparticles 124 based on the total weight of the porous coating 120 (i.e., the total weight of the porous coating 120 refers to the combined weight of the catalyst nanoparticles 124 and the porous oxide 122, not including water or any other diluent, additive, or impurity). For example, in some embodiments, the porous coating 120 may have from 0.1 wt. % to 12 wt. %, from 0.1 wt. % 8 wt. %, from 1 wt. % to 17 wt. %, from 1 wt. % to 12 wt. %, from 1 wt. % to 8 wt. %, from 2 wt. % to 17 wt. %, from 2 wt. % to 12 wt. %, or from 2 wt. % to 8 wt. % catalyst nanoparticles based on the total weight of the porous coating 120.

The porous coating 120 may have a porosity that enables the conductive metal 114 to penetrate into the pores of the porous coating 120 during electroless plating and nucleate at the catalyst nanoparticles 124 dispersed within the porous coating 120. In some embodiments, the porous coating 120 may have a porosity greater than a porosity of the metal oxide substrate 110. The porosity of the porous coating 120 may be defined in terms of the average pore size and average pore volume of the porous coating 120. In some embodiments, the porous coating 120 may have an average pore size sufficient to enable the conductive metal 114 to penetrate into the pores of the porous coating 120 to reach the catalyst nanoparticles 124 dispersed within the porous oxide 122 of the porous coating 120. If the average pore size of the porous coating 120 is too small, then the conductive metal 114 may not penetrate into the porous coating 120 to catalyst nanoparticles 124 embedded within the porous coating 120, which may result in reduced interlocking or other coupling of the conductive metal 114 with the porous coating 120 and, thus, reduced adhesion of the conductive metal 114 to the oxide substrate 110. In some embodiments, the porous coating 120 may have an average pore size greater than an average pore size of the oxide substrate 110. In some embodiments, the porous coating 120 may have an average pore size of greater than or equal to 2 nm, such as greater than or equal to 3 nm, or even greater than or equal to 4 nm. In some embodiments, the porous coating 120 may have an average pore size of less than or equal to 50 nm, less than or equal to 40 nm, less than or equal to 30 nm, less than or equal to 20 nm, or even less than or equal to 10 nm. In some embodiments the porous coating 120 may have an average pore size of from 2 nm to 50 nm. For example, in some embodiments, the porous coating 120 may have an average pore size of from 2 nm to 40 nm, from 2 nm to 30 nm, from 2 nm to 20, from 2 nm to 10 nm, from 3 nm to 50 nm, from 3 nm to 40 nm, from 3 nm to 30 nm, from 3 nm to 20 nm, or from 3 nm to 10 nm.

The use of the porous oxide 122 for the porous coating 120 may enable the pore size of the porous coating 120 to be tuned. For example, in some embodiments, the pore size of the porous coating 120 may be tuned by modifying the particles size of the porous oxide 122 in the porous coating 120. In some embodiments, the pore size of the porous coating 120 may be tuned by modifying the temperature at which the porous coating 120 is heat treated (e.g., calcined). In some embodiments, a pore former, such as polyethylene glycol (PEG) for example, may be incorporated into a coating mixture used to produce the porous coating 120. The pore former may include a material that may be burned away during heat treatment of the porous coating 120 to produce pores in the porous coating 120. Examples of pore formers may include but are not limited to PEG, polyvinyl pyrrolidone (PVP), polymethyl methacrylate, polystyrene, sucrose, waxes, or other solids that combust or transfer into the gas phase at the heat treatment temperatures of the porous coating 120. Tuning the pore size of the porous coating 120 may enable modifying the degree of interlocking between the porous coating 120 and the conductive metal 114, thereby modifying the adhesion between the porous coating 120 and the conductive metal 114. For example, in some embodiments, the pore size of the porous coating 120 may be increased to accommodate the grain size of the conductive metal 114 electrolessly deposited onto the porous coating. In other embodiments, the pore size of the porous coating 120 may be increased, which may enable greater migration of the conductive metal 114 into the pores of the porous coating 120 and greater interlocking between the porous coating 120 and the conductive metal 114.

The porous coating 120 may have an average pore volume that enables sufficient penetration of the conductive metal 114 into the porous coating 120. If the average pore volume of the porous coating 120 is too small, the degree of interlocking or other coupling between the conductive metal 114 and the porous coating 120 may be insufficient to provide adequate bonding of the conductive metal 114 to the porous coating 120. In some embodiments, the porous coating 120 may have an average pore volume greater than an average pore volume of the oxide substrate. In some embodiments, the porous coating 120 may have an average pore volume greater than or equal to 0.20 cubic centimeters per gram (cm³/g), greater than or equal to 0.25 cm³/g, greater than or equal to 0.30 cm³/g, or even greater than or equal to 0.35 cm³/g. In some embodiments, the porous coating 120 may have an average pore volume less than or equal to 1.00 cm³/g, less than or equal to 0.80 cm³/g, or even less than or equal to 0.60 cm³/g. In some embodiments, the porous coating 120 may have an average pore volume of from 0.20 cm³/g to 1.00 cm³/g, from 0.20 cm³/g to 0.80 cm³/g, from 0.20 cm³/g to 0.60 cm³/g, 0.25 cm³/g to 1.00 cm³/g, from 0.25 cm³/g to 0.80 cm³/g, from 0.25 cm³/g to 0.60 cm³/g, 0.30 cm³/g to 1.00 cm³/g, from 0.30 cm³/g to 0.80 cm³/g, from 0.30 cm³/g to 0.60 cm³/g, 0.35 cm³/g to 1.00 cm³/g, from 0.35 cm³/g to 0.80 cm³/g, or from 0.35 cm³/g to 0.60 cm³/g.

Applying the porous coating 120 to the surface 112 of the oxide substrate 110 may include producing a coating mixture, introducing the coating mixture to the surface 112 of the oxide substrate 110, and heat treating the coating mixture to form the porous coating 120 bonded to the surface 112 of the metal oxide substrate 110. The coating mixture may include the porous oxide 122, the catalyst nanoparticles 124, and a diluent. The porous oxide 122 and the catalyst nanoparticles 124 were previously described herein.

In some embodiments, the porous oxide 122 may be provided and added to the coating mixture as an oxide solid particulate, such as a powdered solid. In other embodiments, the porous oxide 122 may be provided and added to the coating mixture as a suspension of porous oxide 122 particles in a diluent such as water or an organic alcohol for example. The porous oxide 122 is included in the coating mixture as the oxide. Some conventional methods of coating a substrate with an oxide coating may use an oxide precursor that reacts to form the oxide during application of the coating to the substrate or heat treatment of the coating mixture. However, it was found that using oxide precursors in the coating mixture instead of oxides (e.g., oxide particles) produced a coating having porosity insufficient to enable effective coupling of the conductive metal 114 with the coating.

In some embodiments, the diluent in the coating mixture may include water, an organic solvent, or combinations of these. In some embodiments, the diluent may include water. Alternatively or additionally, in some embodiments, the diluent may include an organic solvent, such as an organic alcohol, for example. Organic alcohols may be linear or branched alcohols having from 1 to 10 carbon atoms, such as 1, 2, 3, 4, 5, 6, 7, 8, 9, or 10 carbon atoms. Examples of organic alcohols may include, but are not limited to, methanol, ethanol, propanol, isopropyl alcohol, butanol, isobutyl alcohol, hexanol, or combinations of these. Other organic solvents may also be suitable for use as the diluent in the coating mixture.

The coating mixture may be prepared by adding the porous oxide 122 and the catalyst nanoparticles 124 to the diluent and mixing the coating mixture to uniformly distribute the porous oxide 122 and catalyst nanoparticles 124 throughout the diluent. In some embodiments, the coating mixture may be mixed to form a homogeneous suspension of the porous oxide 122 and catalyst nanoparticles 124 in the diluent. The coating mixture may include an amount of the diluent sufficient to produce a homogeneous suspension of the porous oxide 122 and catalyst nanoparticles 124 in the diluent. For example, in some embodiments, the coating mixture may have from 70 wt. % to 99.5 wt. % diluent based on the total weight of the coating mixture, such as from 70 wt. % to 99 wt. %, from 70 wt. % to 95 wt. %, from 70 wt. % to 90 wt. %, from 75 wt. % to 99.5 wt. %, from 75 wt. % to 99 wt. %, from 75 wt. % to 95 wt. %, from 75 wt. % to 90 wt. %, from 80 wt. % to 99.5 wt. %, from 80 wt. % to 99 wt. %, from 80 wt. % to 95 wt. %, or from 80 wt. % to 90 wt. % diluent based on the total weight of the coating mixture. In some embodiments, the amount of diluent in the coating mixture may be adjusted to control a thickness of the porous coating 120 applied to the surface 112 of the oxide substrate 110. For example, increasing the amount of the diluent in the coating mixture may be operable to reduce the thickness of the porous coating 120. Similarly, reducing the amount of the diluent in the coating mixture may operate to increase the thickness of the porous coating 120 applied to the surface 112 of the oxide substrate 110.

Once the coating mixture has been prepared, the coating mixture may be introduced to the surface 112 of the oxide substrate 110. In some embodiments, introducing the coating mixture to the surface 112 of the oxide substrate 110 may include dip coating, spin coating, spray coating, curtain coating, skim coating, roll coating, printing (e.g., screen-printing, ink-jet printing, etc.), brushing, or combinations of these. In some embodiments, the coating mixture may be introduced to the surface 112 of the oxide substrate 110 by dip coating the oxide substrate 110 into the coating mixture. Dip coating processes may include submerging all or a portion of the oxide substrate 110 in the coating mixture. In some embodiments, a mask may be applied to the oxide substrate 110 to prevent application of the porous coating 120 to specific regions of the oxide substrate 110. Dip coating may enable coating of the entire inner surface of the vias 106 (FIG. 6) formed in the oxide substrate 110 with the coating mixture.

The oxide substrate 110 having the coating mixture introduced to the surface 112 of the oxide substrate 110 may be heat treated. In some embodiments, heat treating the coating mixture may include drying the coating mixture, which may be operable to remove at least a portion of the diluent from the coating mixture to form the porous coating 120 bonded to the surface 112 of the oxide substrate 110. In some embodiments, heat treating the coating mixture may include calcining the coating mixture introduced to the surface 112 of the oxide substrate 110. In some embodiments, heat treating the coating mixture applied to the surface 112 of the oxide substrate 110 may include drying and calcining the coating mixture. In some embodiments, the oxide substrate 110 having the coating mixture introduced to the surface 112 of the oxide substrate 110 may be heat treated at a temperature of from 500 degrees Celsius (° C.) to 700° C., such as from 550° C. to 700° C. In some embodiments, the coating mixture may be heat treated for a time of at least one hour. In some embodiments, the coating mixture may be heat treated in air. In other embodiments, the coating mixture may be heat treated in an atmosphere comprising an inert gas, such as nitrogen, helium, argon, other inert gas, or combinations of these.

After heat treating, the porous coating 120 applied to the surface 112 of the oxide substrate 110 may have the average pore size, average pore volume, and weight ratio of porous oxide 122 to catalyst nanoparticles 124 previously described in this disclosure. In some embodiments, the porous coating 120 may have a thickness sufficient to provide interlocking of the conductive metal 114 to the porous coating 120. In some embodiments, the porous coating 120 may have a thickness greater than or equal to 20 nm, such as greater than or equal to 30 nm, or even greater than or equal to 40 nm. If the thickness of the porous coating 120 is too small, such as less than 20 nm for example, then the pores of the porous coating 120 may not extend far enough into the porous coating 120 to provide sufficient interlocking of the conductive metal 114. In some embodiments, the porous coating 120 may have a thickness less than or equal to 200 nm, such as less than or equal to 175 nm, or even less than or equal to 150 nm. In some embodiments, the porous coating 120 may have a thickness of from 20 nm to 200 nm, such as from 20 nm to 175 nm, from 20 nm to 150 nm, from 30 nm to 200 nm, from 30 nm to 175 nm, from 30 nm to 150 nm, from 40 nm to 200 nm, from 40 nm to 175 nm, or from 40 nm to 150 nm.

The catalyst nanoparticles 124 are dispersed within the porous oxide 122 of the porous coating 120 so that the catalyst nanoparticles 124 make up at least a portion of the solid matrix of the porous coating 120. Thus, the catalyst nanoparticles 124 are incorporated into the solid structure of the porous coating 120 compared to being deposited on the outer surface 126 of the porous coating 120 or within the surface pores of the porous coating 120. In some embodiments, the catalyst nanoparticles 124 may be dispersed within the porous oxide 122 over a depth of at least 10% of a thickness t of the porous coating 120, the depth being determined relative to an outer surface 126 (FIG. 5) of the porous coating 120. For example, in some embodiments, the catalyst nanoparticles 124 may be dispersed over a depth of at least 20%, at least 30%, at least 40%, at least 50%, at least 60%, or even at least 70% of the thickness t of the porous coating 120. In some embodiments, the catalyst nanoparticles 124 may be dispersed within the porous coating 120 over a depth of from 10% to 100%, from 20% to 100%, from 30% to 100%, from 40% to 100%, from 50% to 100%, from 60% to 100%, from 70% to 100%, from 10% to 90%, from 20% to 90%, from 30% to 90%, from 40% to 90%, from 50% to 90%, or even from 60% to 90% of the thickness t of the porous coating 120.

As previously discussed, once the porous coating 120 has been applied to the surface 112 of the oxide substrate 110, the conductive metal 114 may be applied to the porous coating 120. In some embodiments, the conductive metal 114 may be an electrical conductor that does not form a strong bond with oxides. In some embodiments, the conductive metal 114 may include one or a plurality of transition metals, where a transition metal refers to any metal defined by IUPAC as “an element whose atom has a partially filled d sub-shell, or which can give rise to cations with an incomplete d sub-shell.” In some embodiments, the conductive metal 114 may include copper (Cu), copper alloys, nickel (Ni), nickel alloys, cobalt (Co), gold (Au), silver (Ag), lead (Pb), platinum (Pt), tin (Sn), cadmium (Cd), chromium (Cr), alloys of these conductive metals, or combinations of these. In some embodiments, the conductive metal 114 may include copper or copper alloys. In some embodiments, the conductive metal 114 may be a metal having an enthalpy of formation of a bond with metal oxides greater than or equal to −100 kilocalories per mol (kcal/mol) (418.4 kilojoules per mol (kJ/mol) where 1 kcal/mol=4.184 kJ/mol) (i.e., a metal for which the corresponding metal oxide has an enthalpy of formation of greater than or equal to −100 kCal/mol). For example, in some embodiments, the conductive metal 114 may be a metal for which the corresponding metal oxide has an enthalpy of formation of greater than or equal to −75 kcal/mol.

The conductive metal 114 may initially be deposited onto the porous coating 120 by an electroless plating process to produce a first metal layer 130 interlocked with the porous coating 120. Electroless plating is a chemical method of plating a surface with a metal that does not require the introduction of an external electrical current to the substrate and plating solution. During electroless deposition of the conductive metal 114 onto the porous coating 120, the oxide substrate 110 having the porous coating 120 applied to the surface 112 may be immersed in a bath of an electroless plating solution. The electroless plating solution may include at least a conductive metal precursor and a reducing agent. The conductive metal precursor may provide a source of the metal ions, such as copper ions or nickel ions for example, to be plated onto the porous coating 120. In some embodiments, the conductive metal precursor may include one or a plurality of conductive metal salts, such metal halides, metal sulfates, metal nitrates, metal phosphates, or other metal salts, or combinations of these. For example, in some embodiments, the conductive metal precursor may include copper sulfate, nickel sulfate, nickel phosphate, copper nitrate, copper phosphate, copper chloride, nickel chloride, or other metal salt, or combinations of metal salts. In some embodiments, the conductive metal precursor may be copper sulfate.

The reducing agent may be capable of reducing the metal ions from the conductive metal precursor to form elemental metal. In some embodiments, the reducing agent may be a low-molecular weight aldehyde, such as but not limited to acetaldehyde or formaldehyde for example. In some embodiments, the reducing agent may be formaldehyde. Other reducing agents, such as but not limited to sulfites, phosphites, formic acid, or other reducing agents, may also be suitable for use in the electroless plating solution.

In some embodiments, the electroless plating solution may include a chelating agent. The chelating agent may be added to modify the plating rate and increase the stability of the electroless plating solution. Chelating agents may include, but are not limited to ethylenediamine tetraacetic acid (EDTA), tartrate, other chelating agent, or combinations of chelating agents.

During the electroless plating process, the catalyst nanoparticles 124 distributed throughout the porous coating 120 may provide nucleation sites for deposition of the conductive metal. By using metal catalysts that are not prone to oxidation, such as silver, gold, cobalt, palladium, or platinum, for the catalyst nanoparticles 124, the surfaces of the catalyst nanop articles 124 may provide elemental metal surfaces for nucleation of the conductive metal without having to first reduce metal oxides formed at the surfaces of the catalyst nanoparticles 124. Therefore, the reducing agent (e.g., formaldehyde) is free to reduce the conductive metal ions provided by the conductive metal precursor to elemental conductive metal. For example, for an electroless plating solution including copper sulfate as the conductive metal precursor, the cupric ions from the copper sulfate are reduced by the reducing agent to metallic copper. Once reduced by the reducing agent, the elemental conductive metal (e.g., metallic copper) may then deposit on the nucleation surfaces of the catalyst nanoparticles 124. This the electroless deposition of the conductive metal 114 onto the porous coating 120 coupled to the surface 112 of the oxide substrate 110 can be accomplished chemically without applying an external electric current. Electroless deposition of the conductive metal 114 onto the nucleation surfaces of the catalyst nanoparticles 124 may result in the conductive metal 114 being metallically bonded to the nucleation surfaces of the catalyst nanoparticles 124.

Because the catalyst nanoparticles 124 are dispersed within and throughout the porous coating 120, the nucleation sites for deposition of the conductive metal 114 are also distributed within and throughout the porous coating 120. During electroless plating, the electroless plating solution penetrates into the pores of the porous coating 120 to enable the conductive metal 114 to nucleate (i.e., seed) on the surfaces of the catalyst nanoparticles 124. As electroless plating proceeds, the conductive metal 114 continues to deposit onto itself to at least partially fill a portion of the pores in the porous coating 120 adjacent to each of the catalyst nanop articles 124. Further deposition of the conductive metal 114 causes the conductive metal 114 to extend through the pores of the porous coating 120 to the outer surface of the porous coating 120, where the conductive metal forms the first metal layer 130. As a result, at least a portion of the conductive metal 114 of the first metal layer 130 extends into the pores of the porous coating 120. The conductive metal 114 deposited within the pores of the porous coating 120 may provide mechanical interlocking between of the first metal layer 130 and the porous coating 120. At the conclusion of electroless plating, the metal oxide substrate 110 includes the porous coating 120 applied to the surface 112 of the oxide substrate 110 and a first metal layer 130 mechanically interlocked or otherwise coupled with the porous coating 120. The conductive metal 114 may be metallically bonded to the catalyst nanoparticles 124 and mechanically interlocked with the porous coating.

Deposition of the conductive metal 114 within the pores of the porous coating 120 may increase mechanical interlocking or other coupling of the conductive metal 114 to the porous coating 120. In some instances, the conductive metal 114 may couple through formation of at least some chemical bonds with the porous coating 120, such as through at least some oxidation of the conductive metal 114 to form metal oxide bonds with the porous coating 120. Additionally, the conductive metal 114 may be metallically bonded to the catalyst nanoparticles 124 embedded within the porous coating. However, it is believed that the chemical and metallic bonding is limited in some aspects and that the contribution of mechanical interlocking of the conductive metal 114 with the pores of the porous coating 120 to the bond strength of the conductive metal 114 is substantially greater than the contribution from chemical and metallic bonding in some aspects.

At the conclusion of the electroless plating, the oxide substrate 110 may be removed from contact with the electroless plating solution. In some embodiments, the oxide substrate 110 having the first metal layer 130 deposited onto the porous coating 120 may be rinsed with water and dried, such as by drying with a heated nitrogen gas stream or other inert gas stream.

In some embodiments, the first metal layer 130 deposited onto the porous coating 120 may have a thickness sufficient to ensure that the outer surface of the porous coating 120 is covered by the first metal layer 130. In other embodiments, the first metal layer 130 may have a thickness sufficient to enable the first metal layer 130 to function as an electrode in a subsequent electroplating process. In some embodiments, the first metal layer 130 may have a thickness greater than or equal to 50 nm, such as greater than or equal to 75 nm, or even greater than or equal to 100 nm. In some embodiments, the first metal layer 130 may have a thickness less than or equal to 500 nm, such as less than or equal to 400 nm, less than or equal to 300 nm, or even less than or equal to 200 nm. Electroless plating proceeds at a rate of deposition of the conductive metal 114 that is substantially less than the deposition rates of other plating processes, such as electroplating processes. Therefore, at thicknesses of the first metal layer 130 greater than 500 nm, it may become more economical to transition from an electroless deposition to an electroplating process. In some embodiments, the first metal layer 130 may have a thickness of from 50 nm to 500 nm, such as from 50 nm to 400 nm, from 50 nm to 300 nm, from 75 nm to 500 nm, from 75 nm to 400 nm, from 75 nm to 300 nm, from 100 nm to 500 nm, from 100 nm to 400 nm, or from 100 nm to 300 nm.

In some embodiments, the first metal layer 130 may have an electrical conductivity sufficient for the first metal layer 130 to be used as an electrode in a subsequent electroplating process. In some embodiments, the first metal layer 130 may have a sheet resistance value of greater than or equal to 0.8 ohms per square, such as greater than or equal to 0.9 ohms per square, or even greater than or equal to 1.0 ohms per square. In some embodiments, the first metal layer 130 may have a sheet resistance value less than or equal to 1.8 ohms per square, such as less than or equal to 1.6 ohms per square, or even less than or equal to 1.4 ohms per square. In some embodiments, the first metal layer 130 may have a sheet resistance value of from 0.8 ohms per square to 1.8 ohms per square, such as from 0.8 ohms per square to 1.6 ohms per square, from 0.8 ohms per square to 1.4 ohms per square, from 0.9 ohms per square to 1.8 ohms per square, from 0.9 ohms per square to 1.6 ohms per square, from 0.9 ohms per square to 1.4 ohms per square, from 1.0 ohms per square to 1.8 ohms per square, from 1.0 ohms per square to 1.6 ohms per square, or from 1.0 ohms per square to 1.4 ohms per square.

The coupling of the conductive metal 114 of the first metal layer 130 with the porous coating 120, which includes mechanical interlocking of the conductive metal 114 with the pores of the porous coating 120, and bonding of the porous coating 120 to the oxide substrate 110 may provide a bond strength of the conductive metal 114 to the oxide substrate 110 sufficient to reduce or prevent separation of the conductive metal 114 from the surface 112 of the oxide substrate 110. The adhesion of the conductive metal 114 to the oxide substrate 110 may be evaluated using the tape test described in ASTM standard D3359. In some embodiments, the article 100 may exhibit minimal or no separation of the conductive metal 114 from the oxide substrate 110 during a tape test conducted in accordance with ASTM D3359 and using a tape having an adhesion strength of 3 newtons per centimeter (N/cm) with copper. In some embodiments, a bond between the conductive metal 114 and the oxide substrate 110 may have a bond strength of greater than or equal to 3 N/cm or greater than or equal to 4 N/cm, as determined in accordance with ASTM D3359 and using a tape having an adhesion strength with the conductive metal of 3 N/cm and 4 N/cm, respectively.

Referring again to FIG. 5, a second metal layer 140 may be deposited onto the first metal layer 130 subsequent to depositing the first metal layer 130 onto the porous coating 120. In some embodiments, the method may further include depositing conductive metal 114 onto the first metal layer 130 to form the second metal layer 140. The second metal layer 140 may be deposited using an electroplating process in which the conductive metal 114 is further electroplated onto the first metal layer 130. As previously described, in some embodiments, the first metal layer 130 may be used as an electrode in the electroplating process to form the second metal layer 140. As the rate of deposition of the conductive metal 114 using electroplating methods is more rapid than the deposition rate using electroless plating, the electroplating may be used to increase the thickness of the conductive metal 114 bonded to the surface 112 of the oxide substrate 110. For example, referring to FIG. 6, once the first metal layer 130 is deposited onto the porous coating 120 using electroless plating, an electroplating may be used to completely fill in the through via 106 with the conductive metal 114.

The method may further include annealing the article 100. Annealing may be performed after deposition of the first metal layer 130 or after deposition of the second metal layer 140 onto the first metal layer 130. Annealing may include heat treating the article 100 at an annealing temperature and for a time period of greater than or equal to 30 minutes. Annealing may be conducted in a vacuum oven. The annealing temperature may be from 150° C. to 500° C. Annealing may be conducted at a single temperature and the temperature may be ramped up to the annealing temperature at a rate of 5° C./minute. In some embodiments, annealing may include multiple steps in which the temperature is progressively increased through a plurality of progressively greater hold temperatures.

Immediately following deposition of the second metal layer 140 onto the first metal layer 130, the article 100 may exhibit an interface between the first metal layer 130 and the second metal layer 140. Not intending to be bound by theory, it is believed that this interface is due to the differences in the arrangement and geometry of the conductive metal 114 of the second metal layer 140 deposited using electroplating compared to the conductive metal 114 of the first metal layer 130 deposited using electroless plating. The annealing process may homogenize the conductive metal 114 such that the first metal layer 130 and the second metal layer 140 may not be distinguishable at an interface following annealing of the conductive metal 114. However, the presence of the first metal layer 130 may be confirmed by examining a cross section of the porous coating 120 and identifying portions of the conductive metal 114 penetrating into the pores of the porous coating 120.

Referring again to FIG. 5, the methods described herein results in direct incorporation of catalytic centers (i.e., the catalyst nanoparticles) within the porous structure of the porous coating 120. This enables the conductive metal 114 to be deposited within the pores of the porous coating 120 to couple (e.g., mechanically interlock) the conductive metal 114 to the porous coating 120, during electroless plating. The method described herein is a solution-based method that is cost-effective and enables the conductive metal 114 to be deposited on planar surfaces of the oxide substrate 110 as well as the interior surfaces of the oxide substrate 110 that define the vias 106 (FIG. 6) extending through the oxide substrate 110. As previously discussed, by using silver, gold, cobalt, palladium, platinum, or other metals that are resistant to oxidation for the catalyst nanoparticles, the methods disclosed herein may enable electroless plating of the conductive metal 114 without the additional step of reducing the catalyst to remove metal oxides from the surface.

Referring again to FIG. 5, the methods previously described herein may be used to produce the article 100 that includes the oxide substrate 110, the porous coating 120 coupled to a surface 112 of the metal oxide substrate 110, and the conductive metal 114 interlocked with the porous coating 120. As previously discussed herein, the porous coating 120 includes the porous oxide 122 and the plurality of catalyst nanoparticles 124 dispersed within the porous oxide 122. The conductive metal 114 may be interlocked with the porous coating 120 so that at least a portion of the conductive metal 114 may extend into the pores of the porous coating 120 to interlock the conductive metal 114 to the porous coating 120.

Referring to FIG. 6, in some embodiments, the article 100 may be a 3D interposer having at least one through via 106 extending through the oxide substrate 110 from the first surface 102 to the second surface 104 of the oxide substrate 110. In some embodiments, the article 100 may have a plurality of vias 106 extending through the oxide substrate 110 from the first surface 102 to the second surface 104 of the oxide substrate 110. Each of the vias 106 may be formed in the oxide substrate 110 by a laser-damage-and-etch process or other process for forming an opening through the oxide substrate 110 from the first surface 102 to the second surface 104. In a laser-damage-etch process, a damage track may be initially formed in the oxide substrate 110 by using a laser to modify the oxide material of the oxide substrate 110 along the damage track. An etching solution may then be applied to the oxide substrate 110, which thins the oxide substrate 110. Because the etching rate of the oxide substrate 110 is faster at the damage track, the damage track is preferentially etched so that the via 106 is opened through the oxide substrate 110. Other available methods of forming the vias 106 in the oxide substrate 110 are also contemplated.

In some embodiments, the porous coating 120 may be bonded to the surfaces 112 of the oxide substrate 110 that define each of the plurality of vias 106 and the conductive metal 114 mechanically interlocked with the porous coating 120 may fill each of the plurality of vias 106 from the first surface 102 to the second surface 104 of the oxide substrate 110. The conductive metal 114 may form a continuous electrical connection between the first surface 102 and the second surface 104 of the oxide substrate 110.

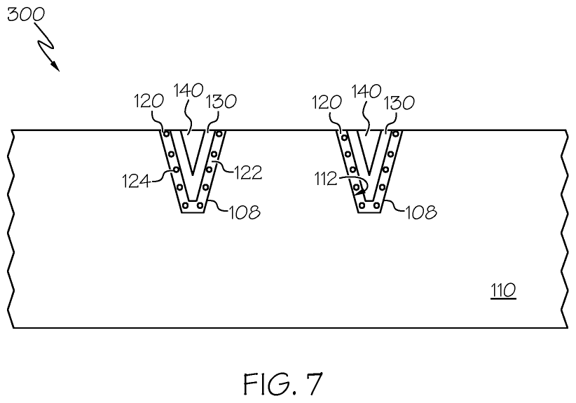

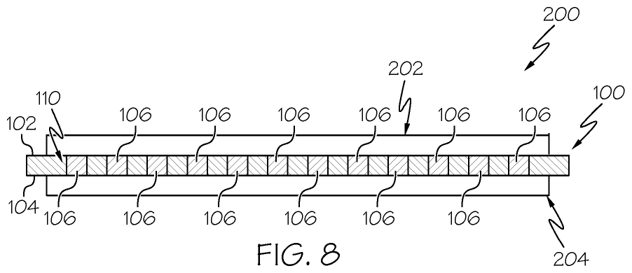

Referring to FIG. 7, in some embodiments, an article 300 may include the substrate 110 having one or a plurality of channels 108 formed in the first surface 102 or the second surface 104. As with the vias 106 previously described relative to FIG. 6, the channels 108 of the article 300 depicted in FIG. 7 may include the porous coating 120 coupled to the surface 112 of the oxide substrate 110 that define the channel 108, the porous coating 120 including the porous oxide 122 and the plurality of catalyst nanoparticles 124. The article 300 may include the conductive metal 114 mechanically interlocked with the porous coating 120. The conductive metal 114 may be initially deposited onto the porous coating 120 by the electroless plating process previously described herein to form the first metal layer 130, which is mechanically interlocked with the porous coating 120. Once the first metal layer 130 is formed, an electroplating process may be used to deposit the second metal layer 140 onto the first metal layer 130. During electroplating, the conductive metal 114 may be progressively built-up until the channel 108 is partially or completely filled with the conductive metal 114. In some embodiments, the article may include a combination of vias 106 (FIG. 6), channels 108 (FIG. 7), or other features. In some embodiments, the surface 112 of the article may be a planar surface, such as the planar surface shown in FIG. 5.

Referring to FIG. 8, the article 100 may be incorporated into an electrical device 200. For example, in some embodiments, an electrical device 200 may include the article 100 and at least one electrical component coupled to the first surface 102 or the second surface 104 of the article 100. In some embodiments, the electrical device 200 may include a first electrical component 202 coupled to the first surface 102 of the article 100 and a second electrical component 204 coupled to the second surface 104 of the article 100. As previously described herein, the article 100 may include one or a plurality of through vias 106 comprising the porous coating 120 coupled to the surfaces 112 of the oxide substrate 110 that define the vias 106. The vias 106 may further include the conductive metal 114 mechanically interlocked with the porous coating 120. In some embodiments, the first electrical component 202 may be electrically coupled to the second electrical component 204 by one or a plurality of the vias 106 extending through the metal oxide substrate 110. For example, in some embodiments, the first electrical component 202 may be in electrical contact with the vias 106 proximate to the first surface 102 of the oxide substrate 110 and the second electrical component 204 may be in electrical contact with the vias 106 proximate the second surface 104 of the oxide substrate 110.

The article may be for use in semiconductor devices, radio-frequency (RF) devices (e.g., antennae, electronic switches, and the like), interposer devices, microelectronic devices, optoelectronic devices, microelectronic mechanical system (MEMS) devices and other applications where vias may be leveraged.

Tape Test

A tape test may be used to assess the strength of the bond between the conductive metal 114 and the surface 112 of the oxide substrate 110. The tape test may be conducted according to ASTM 3359 using a tape having a specific adhesion strength when bonded to the conductive metal. In some embodiments, the tape test may be conducted on a conductive metal that is copper, and the tape used may have a bond strength to copper of 3 N/cm.

### EXAMPLES

The embodiments described herein will be further clarified by the following examples. Unless otherwise indicated, the oxide substrate 110 used for each of the examples was Corning EAGLE XG boro-aluminosilicate glass manufactured by Corning Incorporated.

### Example 1

In Example 1, an article was made using colloidal alumina for the porous metal oxide of the porous coating applied to the surface of a glass substrate. For Example 1, a coating mixture was prepared by adding 100 grams of an alumina suspension to 100 grams of deionized water followed by adding 5 grams of an aqueous solution comprising 10 wt. % silver nanoparticles. The alumina suspension was NYACOL® AL20 colloidal alumina (20 wt. % alumina in water) available from Nyacol Nano Technologies, Inc. The aqueous solution of silver nanoparticles was obtained from Cerion Advanced Materials. The coating mixture was treated with an acoustic mixer at 30% intensity for 10 seconds for better dispersion.

A 2 inch by 2 inch piece of glass substrate was then dipped into the coating mixture and then withdrawn. The glass substrate was EAGLE XG® boro-aluminosilicate glass available from Corning Incorporated of Corning, N.Y. The glass substrate having the coating mixture applied to the surface was dried and then calcined at 550° C. for 1 hour with a ramp rate of 120° C./hour to produce the glass substrate having a porous coating applied to a surface, the porous coating including a porous alumina matrix with a plurality of silver nanoparticles dispersed throughout the porous alumina matrix. The porous coating exhibited an average pore size of 4.3 nm and an average pore volume of 0.37 cm³/g.

The sample was then coated with a first layer of copper using electroless plating. The electroless plating included submersing the sample in an electroless copper bath for 5 minutes. The electroless copper bath was maintained at 43° C. The electroless copper bath included an aqueous solution of copper sulfate, formaldehyde, and a chelating agent. Upon removal from the electroless copper bath, the samples were washed with water and dried under nitrogen. The sheet resistance of the first metal layer of electroless plated copper was measured using a four-point probe and a model ResMap 178 wafer mapping machine obtained from Creative Design Engineering, Inc. The sheet resistance for the first metal layer was measured to be 0.8 ohm/sq.

Following electroless plating, a second layer of copper was added to the sample using an electroplating process. The sample was electroplated using a non-acidic electroplating bath comprising a 1 molar copper sulfate solution. The first metal layer of the sample was attached to a conductive wire, and the sample was immersed in the electroplating bath. Electroplating was carried out at a constant current of 150 milliamps (mA) for a period of 20 minutes. The thickness of the copper layer was measured to be about 1 micron. The samples were then annealed in a vacuum oven at various temperatures for 30 minutes with a ramp rate of 5° C. per minute.

The sample was subjected to a tape test conducted according to ASTM 3359 using a tape having an adhesion strength to copper of 3 N/cm. It was observed that very little of the copper was removed from the surface of the sample as a result of the tape test.

### Example 2

In Example 2, an article was made using gamma-alumina for a portion of the porous metal oxide of the porous coating applied to the surface of a glass substrate. For Example 2, a coating mixture was prepared by adding 10 grams of gamma-alumina powder to 175 grams of deionized water followed by adding 10 grams of NYACOL® AL20 colloidal alumina as a binder and 5 grams of an aqueous solution comprising 10 wt. % silver nanoparticles. The aqueous solution of silver nanoparticles was obtained from Cerion Advanced Materials. The coating mixture was treated with an acoustic mixer at 30% intensity for 10 seconds for better dispersion.

A 2 inch by 2 inch piece of glass substrate was then dipped into the coating mixture and then withdrawn. The glass substrate was EAGLE XG® boro-aluminosilicate glass available from Corning Incorporated of Corning, N.Y. The glass substrate having the coating mixture applied to the surface was dried and then calcined at 550° C. for 1 hour with a ramp rate of 120° C./hour to produce the glass substrate having a porous coating applied to a surface, the porous coating including a porous alumina matrix with a plurality of silver nanoparticles dispersed throughout the porous alumina matrix. The porous coating exhibited an average pore size of 7.2 nm and an average pore volume of 0.45 cm³/g.

The sample was then coated with a first layer of copper using electroless plating. The electroless plating included submersing the sample in an electroless copper bath for 5 minutes. The electroless copper bath was maintained at 43° C. The electroless copper bath included an aqueous solution of copper sulfate, formaldehyde, and a chelating agent. Upon removal from the electroless copper bath, the samples were washed with water and dried under nitrogen. The sheet resistance of the first metal layer of electroless plated copper was measured as described in Example 1. The sheet resistance of the first metal layer of Example 2 was 0.8 ohm/sq.

Following electroless plating, a second layer of copper was added to the sample using an electroplating process. The sample was electroplated using a non-acidic electroplating bath comprising a 1 molar copper sulfate solution. The first metal layer of the sample was attached to a conductive wire, and the sample was immersed in the electroplating bath. Electroplating was carried out at a constant current of 150 milliamps (mA) for a period of 20 minutes. The thickness of the copper layer was measured to be about 1 micron. The samples were then annealed in a vacuum oven at various temperatures for 30 minutes with a ramp rate of 5° C. per minute.

The sample was subjected to a tape test conducted according to ASTM 3359 using a tape having an adhesion strength to copper of 3 N/cm. It was observed that very little of the copper was removed from the surface of the sample as a result of the tape test.

### Comparative Example 3

In Comparative Example 3, an article was made by electroless plating copper directly to the surface of a glass substrate without first applying the porous coating. The glass substrate was EAGLE XG® boro-aluminosilicate glass available from Corning Incorporated of Corning, N.Y. A 2 inch by 2 inch piece of glass substrate was coated with a first layer of copper using electroless plating. The electroless plating process included submersing the sample in an electroless copper bath for 5 minutes. The electroless copper bath was maintained at 43° C. The electroless copper bath included an aqueous solution of copper sulfate, formaldehyde, and a chelating agent. Upon removal from the electroless copper bath, the samples were washed with water and dried under nitrogen. The sheet resistance of the first metal layer of Comparative Example 3 was about 0.2 ohm/sq.

Following electroless plating, a second layer of copper was added to the sample using an electroplating process. The sample was electroplated using a non-acidic electroplating bath comprising a 1 molar copper sulfate solution. The first metal layer of the sample was attached to a conductive wire, and the sample was immersed in the electroplating bath. Electroplating was carried out at a constant current of 150 milliamps (mA) for a period of 20 minutes. The thickness of the copper layer was measured to be about 1 micron (μm). The samples were then annealed in a vacuum oven at various temperatures for 30 minutes with a ramp rate of 5° C. per minute.

The sample of Comparative Example 3 was subjected to a tape test conducted according to ASTM 3359 using a tape having an adhesion strength to copper of 3 N/cm. The sample of Comparative Example 3 failed the tape test. It was observed that a substantial amount of the copper was removed from the surface of the sample of Comparative Example 3 as a result of the tape test.

### Example 4

In Example 4, a porous coating including colloidal alumina and copper nanoparticles was applied to the surface of a glass substrate to evaluate the effectiveness of copper nanoparticles for electroless plating the first metal layer onto the porous coating. For Example 4, a coating mixture was prepared by adding 100 grams of an alumina suspension to 100 grams of deionized water followed by adding 0.5 grams of copper nanoparticles. The alumina suspension was NYACOL® AL20 colloidal alumina (20 wt. % alumina in water) available from Nyacol Nano Technologies, Inc. The coating mixture was treated with an acoustic mixer at 30% intensity for 10 seconds for better dispersion.

A 2 inch by 2 inch piece of glass substrate was then dipped into the coating mixture and then withdrawn. The glass substrate was EAGLE XG® boro-aluminosilicate glass available from Corning Incorporated of Corning, N.Y. The glass substrate having the coating mixture applied to the surface was dried and then calcined at 550° C. for 1 hour with a ramp rate of 120° C./hour to produce the glass substrate having a porous coating applied to a surface, the porous coating including a porous alumina matrix with a plurality of copper nanoparticles dispersed throughout the porous alumina matrix.

The sample was then coated with a first layer of copper using electroless plating. The electroless plating included submersing the sample in an electroless copper bath for 5 minutes. The electroless copper bath was maintained at 43° C. The electroless copper bath included an aqueous solution of copper sulfate, formaldehyde, and a chelating agent. Upon removal from the electroless copper bath, the samples were washed with water and dried under nitrogen. It was observed that the copper nanoparticles in the porous coating were effective at catalyzing electroless plating of copper onto the surface of the porous coating.

While various embodiments of the methods for bonding the conductive metal 114 to a oxide substrate 110 and articles made therefrom have been described herein, it should be understood it is contemplated that each of these embodiments and techniques may be used separately or in conjunction with one or more embodiments and techniques.

Clause 1 of the description discloses:
A method for coupling a conductive metal to an oxide substrate, the method comprising:

applying a coating mixture to a surface of the oxide substrate, the coating mixture comprising an oxide solid particulate and a plurality of catalyst nanoparticles;

heat treating the coating mixture to form a porous coating on the surface of the oxide substrate, the porous coating comprising a porous oxide having pores and a plurality of catalyst nanoparticles dispersed within the porous oxide; and

depositing the conductive metal onto the porous coating, wherein at least a portion of the conductive metal is deposited within the pores of the porous coating to couple the conductive metal to the porous coating.

Clause 2 of the description discloses:
The method of clause 1, wherein the porous coating has an average pore size of from 2 nm to 50 nm.

Clause 3 of the description discloses:
The method of clause 1, wherein the porous coating has an average pore volume of from 0.20 cm3/g to 1.00 cm3/g.

Clause 4 of the description discloses:
The method of any of clauses 1-3, wherein the conductive metal comprises a metal for which the corresponding metal oxide has an enthalpy of formation of greater than or equal to −100 kCal/mol.

Clause 5 of the description discloses:
The method of any of clauses 1-3, wherein the conductive metal comprises at least one of copper, copper alloy, nickel, nickel alloy, cobalt, gold, silver, lead, platinum, tin, cadmium, chromium, or combinations of these.

Clause 6 of the description discloses:
The method of any of clauses 1-5, wherein the oxide substrate comprises at least one of a glass, a glass ceramic, or a ceramic substrate.

Clause 7 of the description discloses:
The method of any of clauses 1-5, wherein the oxide substrate is selected from the group consisting of aluminosilicate glass, alkali aluminosilicate glass, alkaline aluminosilicate glass, borosilicate glass, boro-aluminosilicate glass, alkali aluminoborosilicate glass, alkaline aluminoborosilicate glass, soda-lime glass, and fused silica.

Clause 8 of the description discloses:
The method of any of clauses 1-7, wherein the porous oxide comprises alpha-alumina, beta-alumina, gamma-alumina, silica, titania, zirconia, or combinations of these.

Clause 9 of the description discloses:
The method of any of clauses 1-8, wherein the plurality of catalyst nanoparticles comprises a metal catalyst selected from silver, gold, palladium, platinum, cobalt, or combinations of these.

Clause 10 of the description discloses:
The method of any of clauses 1-8, wherein the plurality of catalyst nanoparticles comprises nanospheres, nanoflakes, nanowires, nanotubes, nanosheets, or combinations of these.

Clause 11 of the description discloses:
The method of any of clauses 1-10, wherein the plurality of catalyst nanoparticles has an average particle size greater than or equal to 50% of the average pore size of the porous coating.

Clause 12 of the description discloses:
The method of any of clauses 1-11, wherein the porous coating comprises a weight ratio of porous oxide to catalyst nanoparticles of from 5:1 to 1000:1.

Clause 13 of the description discloses:
The method of any of clauses 1-12, wherein the catalyst nanoparticles are dispersed within the porous coating at a depth of at least 20% of a thickness of the porous coating from an outer surface of the porous coating.

Clause 14 of the description discloses:
The method of any of clauses 1-12, wherein the catalyst nanoparticles are dispersed within the porous coating at a depth of at least 40% of a thickness of the porous coating from an outer surface of the porous coating.

Clause 15 of the description discloses:
The method of any of clauses 1-14, wherein a bond strength of the conductive metal to the oxide substrate is greater than or equal to 3 newtons per centimeter (N/cm) as determined in accordance with ASTM D3359 and using a tape having an adhesion strength to the conductive metal of 3 N/cm.

Clause 16 of the description discloses:
The method of any of clauses 1-15, wherein the coating mixture further comprises a diluent.

Clause 17 of the description discloses:
The method of clause 16, wherein the applying coating mixture comprises dip coating, spin coating, spray coating, curtain coating, roll coating, printing, brushing, or combinations of these.

Clause 18 of the description discloses:
The method of any of clauses 1-17, wherein the depositing the conductive metal onto the porous coating comprises electroless deposition of the conductive metal onto the porous coating to produce a first metal layer.

Clause 19 of the description discloses:
The method of clause 18, wherein the depositing the conductive metal onto the porous coating further comprises electroplating the conductive metal onto the first metal layer to form a second metal layer bonded to the first metal layer, wherein the first metal layer is used as an electrode in the electroplating.

Clause 20 of the description discloses:
An article made by the method of any of the clauses 1-19.

Clause 21 of the description discloses:
An article comprising:

an oxide substrate;

a porous coating coupled to a surface of the oxide substrate, the porous coating comprising a porous oxide and a plurality of catalyst nanoparticles dispersed within the porous oxide over a depth of at least 20% of a thickness of the porous coating; and

a conductive metal coupled to the porous coating, wherein at least a portion of the conductive metal penetrates into a plurality of pores of the porous coating to interlock the conductive metal to the porous coating.

Clause 22 of the description discloses:
The article of clause 21, wherein the article is a 3D interposer having a plurality of vias extending through the oxide substrate from a first side to a second side of the oxide substrate, wherein the porous coating is bonded to surfaces of the oxide substrate that define each of the plurality of vias and the conductive metal fills each of the plurality of vias from the first side to the second side of the oxide substrate.

Clause 23 of the description discloses:
An electrical device comprising:

the article of clause 21 or 22 having a first side and a second side; and

at least one electrical component electrically coupled to the first side, the second side, or both.

Clause 24 of the description discloses:
An electrical device comprising:

at least one electrical component coupled to a first side or a second side of an article, the article comprising:

an oxide substrate having at least one via;

a porous coating coupled to surface of the oxide substrate that define the at least one via, the porous coating comprising a porous oxide and a plurality of catalyst nanoparticles dispersed within the porous oxide over a depth of at least 20% of a thickness of the porous coating; and

a conductive metal coupled to the porous coating, wherein at least a portion of the conductive metal penetrates into a plurality of pores of the porous coating to interlock the conductive metal to the porous coating.

Clause 25 of the description discloses:
The electrical device of clause 24, wherein the at least one electrical component comprises a first electrical component coupled to the first side of the article and a second electrical component coupled to the second side of the article, and wherein the conductive metal fills the at least one via extending through the article from the first side to the second side to provide an electrical connection between the first electrical component and the second electrical component.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

As used herein, the singular forms “a,” “an” and “the” include plural referents unless the context clearly dictates otherwise. Thus, for example, reference to “a” component includes aspects having two or more such components, unless the context clearly indicates otherwise.

Directional terms as used herein, such as up, down, right, left, front, back, top, bottom, are made only with reference to the figures as drawn and are not intended to imply absolute orientation.

Unless otherwise expressly stated, it is in no way intended that any method set forth herein be construed as requiring that its steps be performed in a specific order, nor that specific orientations be required with any apparatus. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

What is claimed is:

1. A method for coupling a conductive metal to an oxide substrate, the method comprising:
applying a coating mixture to a surface of the oxide substrate, the coating mixture comprising an oxide solid particulate and a plurality of catalyst nanoparticles;
heat treating the coating mixture to form a porous coating on the surface of the oxide substrate, the porous coating comprising a porous oxide having pores and a plurality of catalyst nanoparticles dispersed within the porous oxide; and
depositing the conductive metal onto the porous coating, wherein at least a portion of the conductive metal is deposited within the pores of the porous coating to couple the conductive metal to the porous coating.

2. The method of claim 1, wherein the porous coating has an average pore size of from 2 nm to 50 nm.

3. The method of claim 1, wherein the porous coating has an average pore volume of from 0.20 cm³/g to 1.00 cm³/g.

4. The method of claim 1, wherein the conductive metal comprises a metal for which the corresponding metal oxide has an enthalpy of formation of greater than or equal to −100 kCal/mol.

5. The method of claim 1, wherein the conductive metal comprises at least one of copper, copper alloy, nickel, nickel alloy, cobalt, gold, silver, lead, platinum, tin, cadmium, chromium, or combinations of these.

6. The method of claim 1, wherein the oxide substrate comprises at least one of a glass, a glass ceramic, or a ceramic substrate.

7. The method of claim 1, wherein the oxide substrate is selected from the group consisting of aluminosilicate glass, alkali aluminosilicate glass, alkaline aluminosilicate glass, borosilicate glass, boro-aluminosilicate glass, alkali aluminoborosilicate glass, alkaline aluminoborosilicate glass, soda-lime glass, and fused silica.

8. The method of claim 1, wherein the porous oxide comprises alpha-alumina, beta-alumina, gamma-alumina, silica, titania, zirconia, or combinations of these.

9. The method of claim 1, wherein the plurality of catalyst nanoparticles comprises a metal catalyst selected from silver, gold, palladium, platinum, cobalt, or combinations of these.

10. The method of claim 1, wherein the plurality of catalyst nanoparticles comprises nanospheres, nanoflakes, nanowires, nanotubes, nanosheets, or combinations of these.

11. The method of claim 1, wherein the plurality of catalyst nanoparticles has an average particle size greater than or equal to 50% of the average pore size of the porous coating.

12. The method of claim 1, wherein the porous coating comprises a weight ratio of porous oxide to catalyst nanoparticles of from 5:1 to 1000:1.

13. The method of claim 1, wherein the catalyst nanoparticles are dispersed within the porous coating at a depth of at least 20% of a thickness of the porous coating from an outer surface of the porous coating.

14. The method of claim 1, wherein the catalyst nanoparticles are dispersed within the porous coating at a depth of at least 40% of a thickness of the porous coating from an outer surface of the porous coating.

15. The method of claim 1, wherein a bond strength of the conductive metal to the oxide substrate is greater than or equal to 3 newtons per centimeter (N/cm) as determined in accordance with ASTM D3359 and using a tape having an adhesion strength to the conductive metal of 3 N/cm.

16. The method of claim 1, wherein the coating mixture further comprises a diluent.

17. The method of claim 16, wherein the applying coating mixture comprises dip coating, spin coating, spray coating, curtain coating, roll coating, printing, brushing, or combinations of these.

18. The method of claim 1, wherein the depositing the conductive metal onto the porous coating comprises electroless deposition of the conductive metal onto the porous coating to produce a first metal layer.

19. The method of claim 18, wherein the depositing the conductive metal onto the porous coating further comprises electroplating the conductive metal onto the first metal layer to form a second metal layer bonded to the first metal layer, wherein the first metal layer is used as an electrode in the electroplating.

20. An article made by the method of claim 1.

21. An article comprising:
an oxide substrate;
a porous coating coupled to a surface of the oxide substrate, the porous coating comprising a porous oxide and a plurality of catalyst nanoparticles dispersed within the porous oxide over a depth of at least 20% of a thickness of the porous coating; and
a conductive metal coupled to the porous coating, wherein at least a portion of the conductive metal penetrates into a plurality of pores of the porous coating to interlock the conductive metal to the porous coating.

22. The article of claim 21, wherein the article is a 3D interposer having a plurality of vias extending through the oxide substrate from a first side to a second side of the oxide substrate, wherein the porous coating is bonded to surfaces of the oxide substrate that define each of the plurality of vias and the conductive metal fills each of the plurality of vias from the first side to the second side of the oxide substrate.

23. An electrical device comprising:
the article of claim 21 having a first side and a second side; and
at least one electrical component electrically coupled to the first side, the second side, or both.

24. An electrical device comprising:
at least one electrical component coupled to a first side or a second side of an article, the article comprising:
an oxide substrate having at least one via;
a porous coating coupled to surface of the oxide substrate that define the at least one via, the porous coating comprising a porous oxide and a plurality of catalyst nanoparticles dispersed within the porous oxide over a depth of at least 20% of a thickness of the porous coating; and
a conductive metal coupled to the porous coating, wherein at least a portion of the conductive metal penetrates into a plurality of pores of the porous coating to interlock the conductive metal to the porous coating.

25. The electrical device of claim 24, wherein the at least one electrical component comprises a first electrical component coupled to the first side of the article and a second electrical component coupled to the second side of the article, and wherein the conductive metal fills the at least one via extending through the article from the first side to the second side to provide an electrical connection between the first electrical component and the second electrical component.
